(19) United States
(12) Patent Application Publication
(10) Pub. No.: US 2010/0240531 A1
(43) Pub. Date: Sep. 23, 2010

(54) PROCESS FOR PRODUCING TITANIUM OXIDE LAYERS

(75) Inventors: Thomas Neubert, Braunschweig (DE); Frank Neumann, Braunschweig (DE); Michael Vergohl, Destedt (DE)

Correspondence Address: SCHWEGMAN, LUNDBERG & WOESSNER, P.A., P.O. BOX 2938, MINNEAPOLIS, MN, 55402, US

(73) Assignee: Fraunhofer-Gesellschaft zur Forderung der angewand ten Forschung E.V., Munchen (DE)

(21) Appl. No.: 12/602,019

(22) PCT Filed: May 30, 2008
(86) PCT No.: PCT/EP2008/004339

§ 371 Date: Jun. 4, 2010

(30) Foreign Application Priority Data
Jun. 1, 2007 (DE) 10 2007 025 577.4

(51) Int. Cl. B01J 21/06; C23C 14/08; B32B 17/06; B32B 18/00; G02B 1/00; G02B 1/10

(52) U.S. Cl. 502/350; 427/255.36

(57) ABSTRACT

The present invention relates to a process for the vacuum-based deposition of a titanium oxide layer from the gas phase on a substrate, wherein deposition is carried out from a source containing titanium oxide at a deposition rate of less than 25 nm/s in an oxygen-containing atmosphere and at a substrate temperature of less than 500° C. and, after deposition, the coated substrate is heat treated for a period of at least 30 minutes in an oxygen-containing atmosphere at temperatures in the range from 200° C. to 1000° C.

The present invention relates to a method for the production of titanium oxide layers and to titanium oxide layers produced according to such a method. The titanium oxide coatings produced according to the invention are transparent and have very high photocatalytic activity.

There is understood by photocatalysis a chemical reaction which is initiated by light on special (photocatalytic) surfaces. The speed of such a chemical reaction thereby depends very greatly upon the characteristic of the material of the surface (i.e. for example upon the chemical composition, the roughness and the crystalline structures) and upon the wavelength and also the intensity of the incident light. The most important photocatalytic material is titanium dioxide which is present in the anatase crystal phase (further known photocatalytic materials are zinc oxide, tin oxide, tungsten oxide, K₄NbO₇ and SrTiO₃). Generally UV light or shortwave visible light is used to initiate the photocatalytic reaction. By means of photocatalysis, it is possible to decompose or oxidise almost all organic materials. Frequently strong hydrophilising of the surface (in particular when using titanium dioxide) is associated with the photocatalytic effect. The contact angle for water hereby drops to below 10°, which can be used for example for antimist coatings.

The market for current photocatalytic coatings is dominated very greatly by titanium dioxide, various coating techniques being applied. Very frequently applied are sol-gel techniques in which fine crystalline titanium dioxide particles in a dispersion are applied on the surface to be coated (substrate). Also coating methods from the gas phase are known, in particular with the help of sputter deposition or high-rate electron beam evaporation.

Important fields of use of photocatalytic materials according to the invention are self-cleaning glasses, for example architectural or building glazing or vehicle glazing, self-cleaning and hydrophilic optical components, such as spectacles, mirrors, lenses, optical gratings, antibacterial surfaces, antimist coatings (such as for example in spectacles and automotive vehicle exterior mirrors), surfaces for photocatalytic cleaning of air (for example for decomposing nitrogen oxides or cigarette smoke) and/or water (here e.g. the decomposition of toxic, chemical, organic contaminants in purification plants), superhydrophilic surfaces or the decomposition of water in order to obtain hydrogen. Superhydrophilicity hereby means that the water contact angle is less than 10°.

It is the object of the present invention to provide a method for the production of titanium oxide coatings which have very high photocatalytic activity, and which method can be implemented with commercial, known vacuum coating plants. Furthermore, it is the object of the invention to provide corresponding titanium oxide coatings.

This object is achieved by a method according to claim 1 and also by a titanium oxide layer according to claim 15. Advantageous embodiments of the method according to the invention and of the titanium oxide layers according to the invention are revealed respectively in the dependent claims. Uses of the titanium oxide layers according to the invention are revealed in claim 19.

The present invention is described subsequently with reference to an embodiment. The method according to the invention is hereby configured such that it can be implemented in a vacuum coating plant known to the person skilled in the art (in particular for example a device for electron beam evaporation). The corresponding, underlying device is hence not described in more detail in the present invention, merely the method parameters for implementing the method according to the invention in such a device are represented.

The method according to the invention which is described subsequently in more detail and also the titanium oxide layers obtained therefrom have, relative to the titanium oxide coatings known from the state of the art, the following advantages:
The titanium oxide coatings have very high photocatalytic activities: the measured activities of the coatings according to the invention are up to a factor of 100 higher than the activities of comparable (i.e. having the same thickness and same composition) titanium oxide layers from the state of the art which are produced by means of gas phase deposition methods which are controlled in the already known manner.
The method according to the invention can be implemented with commercial, known vacuum coating plants (PVD-gas phase deposition devices, PVD=physical vapour deposition).
The titanium oxide layers produced according to the invention have high transparency in the visible and in the near infrared spectral range and are hence also suitable for optical applications (for example optical filters, lenses, mirrors, inspection windows, instrument covers).
The layers according to the invention have high hardness and hence offer great mechanical abrasion- and scratch-resistance.

The present invention is now described with reference to a detailed embodiment.

According to the invention, there are deposited in a vacuum coating process, preferably in a PVD coating process and here particularly preferred by means of electron beam evaporation, titanium oxide layers (TiOₓ) with x≦2 from a TiOₓ-containing source (which preferably includes Ti₃O₅) with a layer thickness of a few nanometres up to approx. 1000 nm, preferably of approx. 5 to 500 nm and particularly preferred of 100 nm to 150 nm. The deposition is hereby effected on temperature-resistant or temperature-stable substrates (for example glass, ceramic, metal or also composites hereof) by means of the above-described physical vapour deposition methods, in particular here in addition to the electron beam evaporation by means of sputter deposition, by means of other evaporation coating techniques of even by means of hollow cathode methods.

In the case of substrate materials from which elements (for example sodium) can reach the evaporation-coated titanium oxide coating by diffusion, there is effected firstly, before the deposition of the titanium oxide coating, deposition of a dielectric diffusion barrier on the substrate (likewise by means of the known vapour deposition methods). There can be deposited as such diffusion barrier or barrier layer in particular SiO₂, Al₂O₃, SiNₓ or AlN. Silicon dioxide SiO₂ is deposited for particular preference. In the case of a barrier layer with an average refractive index which is between that of TiO₂ and that of the substrate, in addition improvement in the colour neutrality can also be effected. This is for example possible by means of an Al₂O₃ intermediate layer (layer between substrate and applied titanium oxide coating) or also by means of intermediate layers comprising mixtures which have a refractive index between 1.7 and 2.0.

According to the invention, the deposition of the titanium oxide layer is effected at a low coating rate of preferably <10 nm/sec (particularly preferred <2 nm/sec or even <0.5 nm/s). The power control for the evaporation source can hereby be controlled via in situ measurements of the coating rate by means of an oscillator quartz. The coating rate control can be implemented with a deposition controller by means of an oscillator quartz layer thickness monitor. The substrate is hereby maintained according to the invention preferably at a low temperature, i.e. at a temperature of <approx. 400° C. and preferably of <approx. 100° C., so that amorphous TiOₓ layers are produced.

According to the invention, coating takes place in an oxygen-containing low pressure atmosphere, preferably at pressures of <10⁻³ mbar, particularly preferred at a value of between 10⁻⁴ mbar and 5*10⁻⁴ mbar.

Because of the above-described method parameters of the coating phase, it is possible to deposit X-ray amorphous titanium oxide layers with low density.

If the deposited titanium oxide coating is intended to be used later as antireflection coating, then it is advantageous to deposit a layer system. The layer system hereby preferably comprises a layer stack comprising at least one high-refractive (e.g. having TiO₂) and at least one low-refractive layer component (which has for example SiO₂). The precisely required layer thicknesses of the individual layers can hereby be determined as a function of the purpose of use, respectively by simulation calculations. The number of individual layers of the layer system used in total influences the quality of the antireflection system (the more individual layers used which are applied one on the other, the better the quality in general of the antireflection system). Even four individual layers suffice in practice for simple antireflection coating systems. Advantageously, high-refractive and low-refractive layers are hereby disposed alternately one on the other (i.e. a low-refractive follows a high-refractive, then again a high-refractive etc.). In the case of such a layer system, an approx. 10 nm thick titanium oxide layer is advantageously deposited as uppermost layer (i.e. furthest from the substrate).

Likewise, it can be advantageous to co-evaporate an organic component during the process from a second source during production of a coating according to the invention, the co-evaporated component is hereby extracted by the subsequent tempering process (see subsequent description) so that advantageously a porous layer is produced. The co-evaporated organic material concerns preferably organic colour pigments (e.g. phthalocyanines, azo colourants and/or perylenes). Alternatively hereto or also additionally, also an inorganic material can be co-evaporated in order to increase the activation capacity during longwave excitation; this can thereby concern for example V, W, Co, Bi, Nb, Mn.

Such a co-evaporation from a second (or third) source can hence be effected in particular in order to produce a high activation capacity with long wave excitation in the case of a titanium oxide layer deposited according to the invention.

According to the above-described coating process, a heat treatment of the coated component is effected according to the invention in an oxygen-containing atmosphere. This heat treatment is advantageously effected at an almost constant temperature and at temperatures between 300 and 800° C., preferably between 500 and 700° C., particularly preferred at 600° C., and at normal pressure. The preferred oxygen proportion of the oxygen-containing atmosphere hereby is between 10 and 30% by volume, particularly preferred 27% by volume. It can also be heat-treated in air. The heat treatment is hereby effected over at least ½ h, advantageously over approx. 1 h.

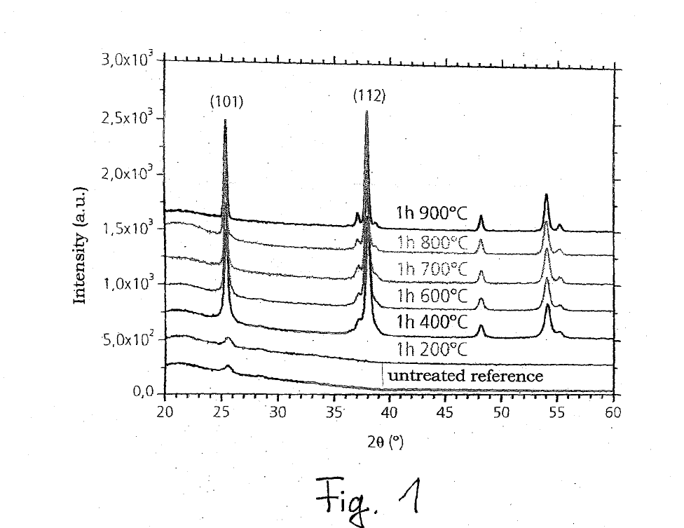

As a result of the second essential step according to the invention of the heat treatment, oxidation and crystallisation processes are initiated in the layers in which purely anatase TiO₂ crystallites are produced. For this purpose, FIG. 1 shows the diffraction pattern obtained with an X-ray diffraction according to the Bragg equation

nλ=2d sin(Θ)

λ being the wavelength of the X-ray radiation radiated onto the titanium oxide layer produced according to the invention, d being the spacing of the crystal planes of the crystallites, Θ being the angle at which the radiation impinges on the crystal plane and n being a whole number.

FIG. 1 shows, on the abscissa, the angle 2 Θ and, on the ordinate, the reflected X-ray intensity. The individual represented curves show the corresponding diffraction intensity as a function of a one-hour heat treatment at different temperatures (the main maxima correspond here to the 101- and 112-crystal plane). The illustrated X-ray diffractograms were determined for heat-treated TiO₂ layers on glass.

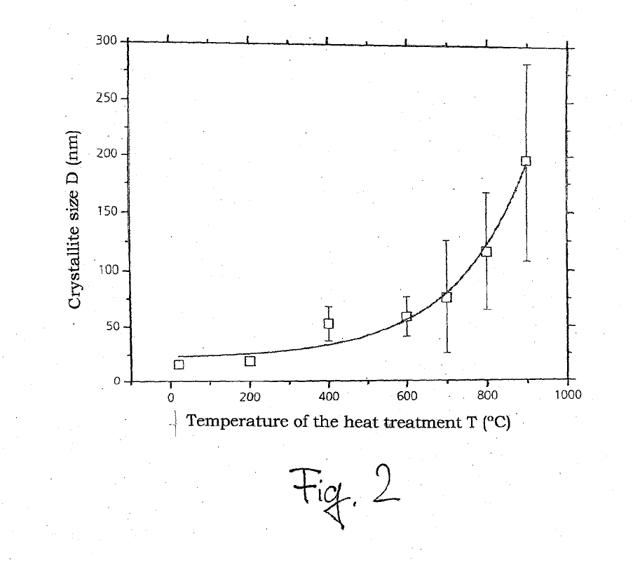

FIG. 2 shows the crystallite size D (in nm) for the above-described example according to FIG. 1, said size increasing with rising temperature of the heat treatment.

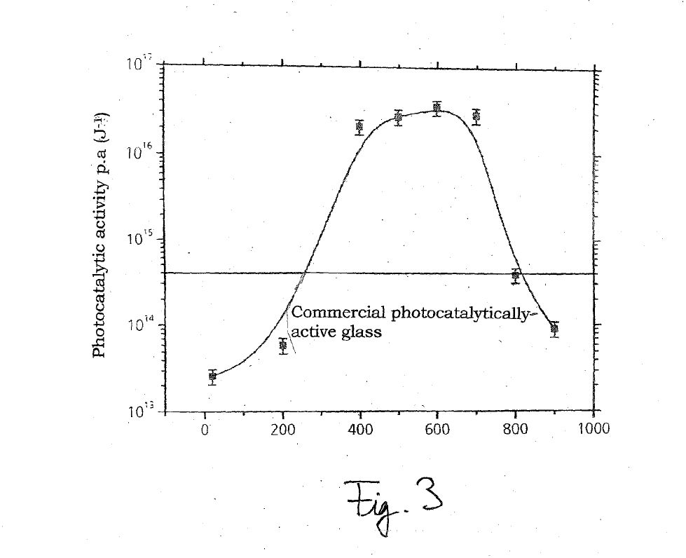

FIG. 3 shows, for the example according to FIGS. 1 and 2, the measured photocatalytic activity after the heat treatment likewise as a function of the treatment temperature (one-hour heat treatment, data on the abscissa in ° C.). As can be deduced from FIGS. 2 and 3, the measured photocatalytic activity increases with increasing crystallite size or with rising temperature (the crystallite size increases herewith, cf. FIG. 2) firstly steeply, then drops again greatly for temperatures above 700° C. Surprisingly, obviously an optimum exists for the treatment temperature of the heat treatment, said temperature being approx. 600° C. in the example described here. In the example described here, the source material Ti₃O₅ was evaporated by means of electron beam evaporation (substrate material: quartz glass). The coating rate was 0.2 nm/sec at a spacing of source and substrate of 55 cm and an oxygen partial pressure of 2*10⁻⁴ mbar. The vapour-deposited layer thickness was 300 nm.

Furthermore, it was established that it is particularly advantageous, with respect to the heat treatment, to apply a high heating and cooling rate for the coated substrate (preferably of >100° C./min), i.e. to heat the substrate rapidly and to cool it again rapidly at the end of the heat treatment in order to achieve high photocatalytic activity.

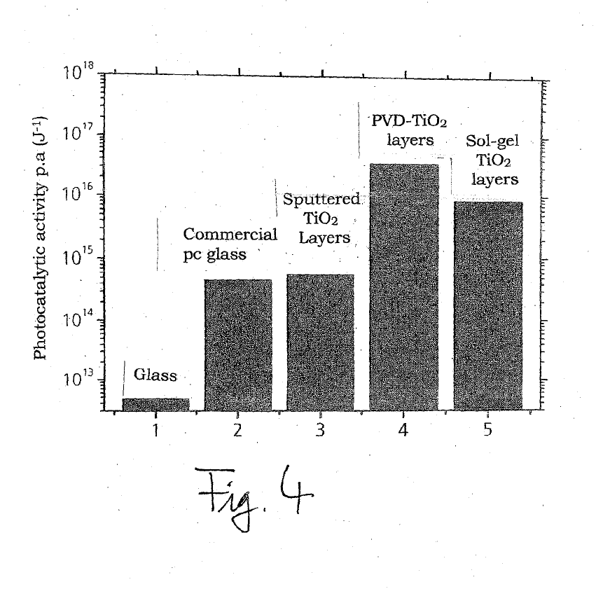

Because of the low density of the layers which is typical of evaporation coating processes, the layers which are heat-treated at the optimum temperature (here approx. 600° C.) are porous and hence have a large surface which is available for photocatalytic reactions. Together with the crystallinity, this explains the good photocatalytic activity of the layers. In photocatalytic decomposition measurements (for example photocatalytic decomposition of stearic acid), it could be shown that layers produced in this way have a higher photocatalytic activity than other comparable layers produced with methods not according to the invention (see FIG. 4 in this respect which compares various transparent photocatalytic TiO₂ coatings with respect to their photocatalytic activity; sample 4 (abscissa: sample number) hereby corresponds to the coating according to the invention).

As already shown, in particular glasses or temperature-stable ceramics can be provided according to the invention with a coating, in particular also with an antireflection coating. Glasses can concern in particular spectacle glass, window glass, glass for household objects (for example for instrument covers in cookers or the like) or glass for lighting objects, such as in particular lamps or lights.

1. A method for vacuum-based deposition of a titanium oxide layer from the gas phase on a substrate, comprising:
depositing from a titanium oxide-containing source with a deposition rate of less than 10 nm/s, in an oxygen-containing atmosphere and at a substrate temperature of less than 500° C.; and
heat treating the coated substrate, after the deposition, over a period of time of at least 30 min in an oxygen-containing atmosphere at temperatures between 200° C. and 1000° C.

2. The method according to claim 1,
wherein
the depositing comprises depositing at a substrate temperature of less than 400° C.

3. The method according to claim 1,
wherein
the depositing takes place in an oxygen-containing atmosphere at a pressure of less than 5·10⁻³ mbar.

4. The method according to claim 1,
wherein at least one of:
the heat treating takes place in an oxygen-containing atmosphere at a temperature between 300° C. and 800° C.; and/or
the heat treating takes place in an oxygen-containing atmosphere at an oxygen volume proportion between 5% and 40%; and/or
the oxygen-containing atmosphere used for the heat treating is air; and/or
the heat treating takes place at normal pressure.

5. The method according to claim 1,
wherein
the titanium oxide-containing source contains or comprises TiOₓ with x≦2.

6. The method according to claim 1,
wherein
the duration of the heat treating is at least 45 min and at most three hours.

7. The method according to claim 1,
wherein
the deposition rate is less than 5 nm/s.

8. The method according to claim 1,
wherein
the titanium oxide layer comprises a thickness>0 nm and ≦2000 nm.

9. The method according to claim 1,
wherein
the deposition takes place on a glass, a ceramic or a metal or a composite of at least one of the above-mentioned materials as the substrate.

10. The method according to claim 1,
wherein
the deposition comprises a physical vapour deposition process, a hollow cathode method or an evaporation coating technique.

11. The method according to claim 1,
wherein at least one of
the coated substrate is heat-treated at an essentially constant temperature, the heating rate for adjusting this essentially constant temperature being greater than 50° C. per minute, and/or
the cooling rate for the coated substrate at the end of its heat treatment is greater than 50° C. per minute.

12. The method according to claim 1,
wherein
the depositing comprises depositing an inorganic material from a second source, the inorganic material including V, W, Co, Bi, Nb and/or Mn.

13. The method according to claim 1,
wherein
a dielectric diffusion barrier layer is deposited before deposition of the titanium oxide layer on the substrate, said diffusion barrier layer preferably comprising SiO₂, Al₂O₃, Si₃N₄ and/or AlN and particularly preferred SiO₂.

14. The method according to claim 1,
wherein
a layer system which has a plurality of individual layers is deposited on the substrate, the layer furthest from the substrate preferably having a thickness of greater than 2 and less 200 nm, the layer system comprising high-refractive layers comprising TiO₂ and low-refractive layers comprising SiO₂ being deposited alternately.

15. A titanium oxide layer configured on a substrate by
deposition of the material vapour of a titanium oxide-containing source in a vacuum chamber with a deposition rate of less than 25 nm/s, in an oxygen-containing atmosphere and at a substrate temperature of less than 400° C. and
heat treatment of the coated substrate after the deposition over a period of time of at least 30 min in an oxygen-containing atmosphere and at a temperature between 400° C. and 700° C.

16. The titanium oxide layer configured on a substrate according to claim 15,
wherein
the titanium oxide layer is configured by depositing in an oxygen-containing atmosphere at a pressure of less than 5·10⁻³ mbar.

17. The titanium oxide layer configured on a substrate according to claim 15,
wherein at least one of:
the substrate comprises a glass element; or
the substrate comprises an optical constructional element or component; or
the substrate comprises a ceramic.

18. The titanium oxide layer according to claim 15, wherein the titanium oxide layer is included in at least one of an antireflection coating, antimist coating, antibacterially-acting surface element, photocatalytically air- and/or water-cleaning surface element, superhydrophilic surface element or surface element configured for decomposing water into hydrogen and oxygen.

19. The titanium oxide layer according to claim 15, wherein the titanium oxide layer is included in at least one of a building glass, a window glass, an automobile glass, a minor glass, an automotive vehicle exterior minor glass, a spectacle glass, a copier glass, a camera lens, a household cooker, an article of furniture, or a lighting object glass, a lamp, a light, an optical constructional element or component, a lens, an optical grating, a ceramic, an article of jewelry, an antireflection coating, an antimist coating, an antibacterially-acting surface, a photocatalytically air- and/or water-cleaning surface, a superhydrophilic surface, or a surface configured to decompose water into hydrogen and oxygen.

20. The method of claim 1, wherein the depositing comprises depositing at a substrate temperature of less 100° C.
